(19) United States
(12) Patent Application Publication
(10) Pub. No.: US 2024/0395994 A1
(43) Pub. Date: Nov. 28, 2024

(54) COMPONENT WITH A PLURALITY OF SEMICONDUCTOR CHIPS

(71) Applicant: ams-OSRAM International GmbH, Regensburg (DE)

(72) Inventors: Gunnar PETERSEN, Regensburg (DE); Andreas REITH, Steinach (DE); Daniel RICHTER, Bad Abbach (DE)

(21) Appl. No.: 18/696,972

(22) PCT Filed: Sep. 23, 2022
(86) PCT No.: PCT/EP2022/076517

§ 371 Date: Mar. 28, 2024

(30) Foreign Application Priority Data
Sep. 28, 2021 (DE) 10 2021 125 056.0

(51) Int. Cl. H01L 33/62; B60Q 1/04; H01L 25/075; H01L 33/50; H01L 33/60

(52) U.S. Cl. CPC H01L 33/62; H01L 25/0753; B60Q 1/04; H01L 33/50; H01L 33/60

(57) ABSTRACT

A component comprising a plurality of semiconductor chips and a carrier is disclosed, wherein the carrier has a common metallic carrier layer with a mounting surface on which the semiconductor chips are arranged. The semiconductor chips are thermally but not electrically conductively connected to the common metallic carrier layer. The carrier has a plurality of contact layers, which are arranged next to one another and next to the common carrier layer in lateral directions and are configured for electrically contacting the component and thus for electrically contacting the semiconductor chips. The carrier has an electrically insulating housing material which holds the common metallic carrier layer and the contact layers together, wherein the common metallic carrier layer and the contact layers are adjacent to the housing material and are electrically insulated from one another by the electrically insulating housing material.

A component with a plurality of semiconductor chips is disclosed. In particular, the component is a module, such as a light module, with a plurality of semiconductor chips for a headlight.

A light module for a headlight usually has a plurality of semiconductor chips, in particular a plurality of discrete so-called CSP (chip-size packages). Such semiconductor chips should be arranged as close together as possible, wherein the semiconductor chips should each be connected electrically and thermally efficiently. The electrical and thermal connections of the semiconductor chips are often located directly under the light-emitting surfaces of the semiconductor chips. The electrical connection and thermal connection of the semiconductor chips therefore pose major technical challenges. In addition, the lateral distances between the semiconductor chips can often not be arbitrarily small, so that in some cases there is a risk that the entire light-emitting surface of the component or light module is not continuous. One possible solution to this problem is the use of IC chips (integrated circuit chips) on which the semiconductor chips are mounted. In many cases, this makes it possible to achieve small distances between the semiconductor chips and a homogeneous light-emitting surface. However, this approach is very cost-intensive.

One task is to specify a compact and cost-effective component, in particular a compact and cost-effective light module, with as homogeneous a light-emitting surface as possible and a secure thermal and electrical connection.

This task is solved by the component according to the independent claim. Further embodiments and further implementations of the component are the subject of the dependent claims.

According to at least one embodiment of a component, it comprises a plurality of semiconductor chips, wherein the thermal connection and the electrical connection of the semiconductor chips are separated from each other. For example, the semiconductor chips are arranged on a common thermal connection pad, wherein the common thermal connection pad is not configured for electrically contacting the semiconductor chips or other electrical or optoelectronic parts.

The thermal connection pad can be a common carrier layer, in particular a common metallic carrier layer. The component can have a plurality of contact layers that are configured for electrically contacting the component and thus for electrically contacting the semiconductor chips. In particular, contact layers are laterally spaced from the common thermal connection pad or from the common carrier layer. The contact layers can have surfaces that form contact pads or soldering surfaces. In the top view of the component, the semiconductor chips can be arranged exclusively on the carrier layer. For example, the semiconductor chips do not overlap with the contact layers in plan view, except for possible electrical connections. The common carrier layer and the contact layers can be formed from the same material or from different materials.

According to at least one embodiment of the component, it has a carrier on which the semiconductor chips are arranged. Such a carrier is in particular different from a simple chip carrier. The carrier may have a carrier layer and a plurality of contact layers, wherein the contact layers are arranged next to each other and next to the carrier layer in lateral directions. The carrier may have a housing body, wherein the housing body is formed in particular from an electrically insulating housing material. The carrier layer and the contact layers can be directly adjacent to the housing material, wherein the carrier layer and the contact layers are mechanically connected to each other.

The housing material can be applied to and around the carrier layer and the contact layers by a molding process or a plastic molding process. In particular, several carriers for several components can be produced simultaneously by the molding process or plastic molding process. In this case, the housing material can, for example, be applied by a molding process or a plastic molding process on and around the initially, in particular, contiguous carrier layers and on and around the initially, for example, partially contiguous contact layers before the carriers or the components are singulated. After singulation, side surfaces of the components and/or the carriers may have traces of singulation. In particular, the contact layers and the carrier layer of a singulated carrier or a singulated component may be sectionally exposed on the side surfaces of the singulated carrier or the singulated component. For example, the housing body is a mold body.

A molding process or a plastic molding process is generally understood to be a method by which a molding compound, in this case the housing body, is shaped, preferably under pressure, according to a predetermined shape and, if necessary, cured. In particular, the term “molding process” or “plastic molding process” includes at least dispensing, jetting, injection molding, injection molding, transfer molding and compression molding. The housing body is formed from the housing material, in particular from a plastic material, such as from a molding material or a castable material. It is possible for the housing body to be formed using a film-assisted molding process.

For example, the carrier is a QFN carrier (Quad Flat No-leads). With such a carrier, the contact layers and/or the carrier layer do not protrude laterally from the housing body. However, it is possible for the contact layers and/or the carrier layer to be sectionally flush with the housing body. The carrier can have side surfaces that are formed sectionally by surfaces of the housing body and sectionally by surfaces of the contact layers and/or the carrier layer. The carrier has a front side and a rear side facing away from the front side, wherein the contact layers and/or the carrier layer can be freely accessible both on the front side and on the rear side. The contact layers and/or the carrier layer can extend throughout the housing body along a vertical direction.

A lateral direction is understood to be a direction that is in particular parallel to a main extension surface of the carrier, for example parallel to a mounting surface of the carrier. A vertical direction is understood to be a direction that is in particular perpendicular to the main extension surface of the carrier or to the mounting surface of the carrier. The vertical direction and the lateral direction are orthogonal to each other.

During operation of the component, the semiconductor chips are configured in particular to generate electromagnetic radiation, for example in the infrared, visible or ultraviolet spectral range. For example, the semiconductor chips are light-emitting diodes (LEDs). The housing material can be a molding material, in particular a radiation-non-transmissive molding material.

In at least one embodiment of a component, it has a plurality of semiconductor chips and a carrier. The carrier has a common metallic carrier layer with a mounting surface on which the semiconductor chips are arranged. The semiconductor chips are thermally but not electrically conductively connected to the common metallic carrier layer. The carrier has a plurality of contact layers that are arranged next to each other and next to the common carrier layer in lateral directions. The contact layers are configured to electrically contact the semiconductor chips. In particular, the contact layers are thus configured for electrically contacting the component. The carrier has an electrically insulating housing material which holds the common metallic carrier layer and the contact layers together, wherein the common metallic carrier layer and the contact layers are adjacent to the housing material and are electrically insulated from one another by the electrically insulating housing material.

Due to the separate thermal and electrical connection of the semiconductor chips, the semiconductor chips can be arranged very close to each other on the mounting surface, in particular very close to each other on the common carrier layer. Lateral distances between the semiconductor chips or between the rows of semiconductor chips, for example all lateral distances between the neighboring semiconductor chips, can be smaller than 150 μm, smaller than 100 μm, smaller than 80 μm or smaller than 60 μm, for example from 30 μm to 150 μm, from 30 μm to 100 μm, from 40 μm to 100 μm, from 40 μm to 80 μm, from 30 μm to 60 μm and from 30 μm to 50 μm.

The electrical connectivity of the semiconductor chips is made, for example, by electrical connections, which may be in the form of wire connections, such as bonding wire connections, or in the form of planar electrical connections. From the semiconductor chips, which are arranged in particular exclusively on the carrier layer, electrical connections can be routed laterally outwards to the contact layers. The contact layers can have surfaces that are formed as soldering surfaces or contact pads. In plan view, the electrical connections can bridge intermediate areas between the common carrier layer and the contact layers. The intermediate areas can be filled with the housing material. This allows the thermal path to be separated from the electrical path. In particular, p-n-junctions of the semiconductor chips are not electrically conductively connected to the common carrier layer. The semiconductor chips can therefore be placed particularly close to each other on the common carrier layer without the risk of short circuits.

According to at least one embodiment of the component, the semiconductor chips have chip carriers or rear sides, wherein the chip carriers or the rear sides face the common carrier layer and are electrically insulating. For example, the semiconductor chips each have a chip carrier which is arranged facing the common carrier layer. In particular, the chip carrier or the rear side of the chip carrier is electrically insulating. For example, the chip carrier is an electrically insulating substrate, such as a ceramic substrate or an electrically insulating growth substrate. The rear side of the semiconductor chip can be formed directly by a surface of the chip carrier. Alternatively or additionally, it is possible for the chip carrier to have an electrically insulating cover layer. In this case, it is possible that the chip carrier has an electrically conductive main body, wherein the electrically conductive main body is covered by the electrically insulating cover layer and is thus electrically insulated from the metallic carrier layer. In particular, the rear side of the chip carrier is formed by a surface of the electrically insulating cover layer.

By using semiconductor chips whose rear sides are electrically insulating, it is possible to mount the semiconductor chips particularly close to a thermal connection pad, in particular to the common carrier layer. As the vertical distance between the common carrier layer and the semiconductor chips is particularly small in this case, the cooling of the semiconductor chips during operation of the component can be made particularly efficient. Along the vertical direction, for example, there is only an electrically insulating or electrically conductive connecting layer between the carrier layer and the semiconductor chips. The bonding layer can be an adhesive layer or a solder layer. In particular, the bonding layer is directly adjacent to both the mounting surface and the semiconductor chips.

According to at least one embodiment of the component, the semiconductor chips are electrically conductively connected to the contact layers via wire connections, in particular via bonding wire connections. Alternatively, the semiconductor chips can be electrically conductively connected to the contact layers via planar electrical connections. For example, the semiconductor chips each have electrical contact points that are located on the front sides of the semiconductor chips. In particular, the semiconductor chips can be electrically contacted exclusively via their front sides. For example, the electrical contact points are located on the side of the light-emitting surface of the respective semiconductor chip. The electrical contact points can be arranged at the same vertical height or vertically offset.

According to at least one embodiment of the component, the carrier has a front side and a rear side facing away from the front side, with the front side comprising the mounting surface. The contact layers can be accessible on both the front side and the rear side of the carrier. In other words, the contact layers can be exposed sectionally on both the front side and the rear side of the carrier.

If the housing material forms a housing body that mechanically holds the contact layers and the carrier layer together, the contact layers can extend through the housing body along the vertical direction. It is also possible for the carrier layer to extend through the housing body along the vertical direction. The contact layers and the carrier layer can be formed from the same material or from different materials. For example, it is possible that the contact layers and the carrier layer are originally formed from a common metal layer. To form the contact layers and the carrier layer, the common metal layer is structured, for example etched, and possibly singulated after the housing body has been formed. In this sense, the carrier layer and the contact layers form a lead frame of the carrier or component.

The carrier layer and/or the contact layers can have regions with reduced vertical layer thicknesses. Such regions can be formed in stepped manner. For example, the carrier layer is partially etched, for example half etched, in such regions. In particular, these regions form anchoring structures to which the housing material is anchored. Displacement or removal of the housing body from the carrier layer or from the contact layers is thus prevented or made more difficult.

According to at least one embodiment of the component, the semiconductor chips are configured to generate electromagnetic radiation during operation of the component. For example, the semiconductor chips are light-emitting diodes (LEDs). For example, the semiconductor chips are arranged in at least one row or in at least two rows on the mounting surface. For example, the semiconductor chips are controllable individually via the plurality of the contact layers or connected in series or parallel. It is also possible for the semiconductor chips to be arranged in a matrix-like manner, i.e. in several rows and columns on the mounting surface. It is also possible for the semiconductor chips to be arranged in exactly one row or exactly two rows on the mounting surface.

According to at least one embodiment of the component, it has a housing body. In particular, the housing body is formed from the housing material. The component is formed, for example, as a QFN component (Quad Flat No-leads). In a QFN component, the contact layers in particular are at most flush with the housing body in lateral directions. In other words, the contact layers do not protrude laterally beyond the housing body. If the contact layers are flush with the housing body, the component, in particular the carrier of the component, can have side surfaces that are formed sectionally by surfaces of the housing body and sectionally by surfaces of the contact layers. Within the manufacturing tolerances, the contact layers therefore do not protrude laterally beyond the housing body. In particular, the component or the carrier of the component does not have any electrical contact structures that are partially embedded in the housing body and protrude laterally beyond the housing body.

According to at least one embodiment of the component, it has a housing body formed from the housing material. When viewed from above, the housing body has in particular a frame-like structure. For example, the housing body has an opening which, in plan view, is framed by side walls of the housing body. In particular, the side walls of the housing body are vertical elevations above the mounting surface. The opening is in particular a depression in the housing body. The contact layers can be partially covered by the side walls of the housing body and partially exposed in the opening of the housing body. The opening has a bottom surface, which can be formed sectionally by the mounting surface, sectionally by surfaces of the contact layers and/or sectionally by surfaces of the housing material. Alternatively, it is also possible for the housing body to be flush with the metallic carrier layer and/or with the contact layers on a front side and/or on a rear side of the carrier.

According to at least one embodiment of the component, it has an encapsulation layer. The encapsulation layer can be formed from a matrix material with reflective particles embedded therein, such as TiO2. The encapsulation layer can partially cover the mounting surface and the contact layers when viewed from above. For example, radiation exit surfaces of the semiconductor chips are not covered by the encapsulation layer.

According to at least one embodiment of the component, it has at least one converter layer or a plurality of converter layers, wherein the converter layer or the plurality of converter layers is/are configured to convert at least some radiation parts of the electromagnetic radiation emitted by the semiconductor chips during operation of the component. For example, the converter layer or the plurality of converter layers is/are laterally adjacent to the encapsulation layer, for example directly adjacent to the encapsulation layer.

In one embodiment of a headlight, it has a component described here. The features described in connection with the component can therefore also be used for the headlight with such a component. In particular, the headlight is a front headlight of a vehicle, such as an automobile. For example, the component described herein or a plurality of the components described herein is an integral part or integral parts of an ADB module (Adaptive/Advanced Driving Beam Module) or an AFS module (Adaptive/Advanced Front-lighting System Module).

According to the present disclosure, rear-side-insulated semiconductor chips are mounted in particular on a common contiguous metal pad of a so-called QFN lead frame. The metallic pad is, in particular, the carrier layer. The QFN lead frame includes, for example, the carrier layer and the contact layers. It is possible that protective diodes, such as ESD chips (electro-static discharge chips), are embedded in or integrated within the housing body, for example within the mold body. As the chip carriers of the rear-side-insulated semiconductor chips, such as the LED chips, are protected by the electrical supply lines, especially from the contact layers, the semiconductor chips can be placed very close together without causing electrical short circuits.

Both p- and n-contacts of the semiconductor chips can be electrically conductively connected to the contact layers via flat electrical connections, for example in the form of bonding wires or planar electrical connections. The individual semiconductor chips can be placed in one or more strands can be electrically connected in series. The electrical connections can be protected from external mechanical influences and environmental influences, for example, by means of an encapsulation material that forms an encapsulation layer. In plan view, the electrical connections can be at least partially or completely covered by the encapsulation layer.

In the presence of the encapsulation layer, which is formed to be radiation reflective in particular, the light emitted from the converter layer, which is for example adjacent to the encapsulation layer, can be reflected to the side back into the converter layer or in a forward direction. The converter layer can be realized by a thin layer, for example in the form of a spray-coating layer or in the form of a thin converter plate with specially adapted converter particles. The encapsulation layer can also lead to a high contrast on one radiation exit side of the component.

As the semiconductor chips are arranged very close to each other, a high luminance and a homogeneous light-emitting surface with the lowest possible brightness fluctuations in the areas between the semiconductor chips can be realized. As the semiconductor chips are also arranged on a common contiguous thermal pad, the thermal cooling can be significantly improved. This means that the component can meet the requirements for use in a headlight, in particular in a front headlight. For example, the component is part of a so-called ADB module (Adaptive/Advanced Driving Beam Module).

According to at least one embodiment of the component, the mounting surface is provided with an electrically insulating additional layer, wherein the electrically insulating additional layer electrically insulates the semiconductor chips from the common metallic carrier layer. In this case, the semiconductor chips can have rear sides that are sectionally or completely electrically conductive. Due to the presence of the electrically insulating additional layer, the metallic carrier layer of the carrier is not electrically conductively connected to the semiconductor chips.

According to at least one embodiment of the component, the semiconductor chips are arranged in at least four rows on the mounting surface. Each of the at least four rows may have at least 5, 8, 10, 12, 16 or at least 20 semiconductor chips. For example, the number of semiconductor chips per row is from 4 to 40, from 5 to 30, from 8 to 25, from 8 to 16 or from 8 to 12. It is also possible that the component has exactly 2, 4, 6 or exactly 8 such rows of semiconductor chips.

According to at least one embodiment of the component, it has a plurality of pixel groups. The pixel groups can each have at least two or more semiconductor chips, with the at least two or more semiconductor chips of the same pixel group each forming a subpixel. For example, the semiconductor chips of the same pixel group are electrically interconnected internally. Due to the internal electrical interconnection, the semiconductor chips of the same pixel group are controllable individually or in groups. Such a pixel group can form an independent multi-pixel whose semiconductor chips each form a sub-pixel. The pixel group or the multi-pixel is thus a contiguous, independent and mechanically stable sub-unit of the component. To form the pixel group or the multi-pixel, the semiconductor chips can be electrically interconnected and encapsulated with an electrically insulating material. Due to the internal interconnection, the semiconductor chips of the same pixel group can be interconnected in series.

According to at least one embodiment of the component, the at least two or more semiconductor chips of the same pixel group comprise a first semiconductor chip and a second semiconductor chip. The first semiconductor chip and the second semiconductor chip each have, for example, a first electrode and a second electrode, wherein the first electrode and the second electrode are assigned to different electrical polarities of the component. The first electrode of the first semiconductor chip can be electrically conductively connected to a first contact layer of the component. The second electrode of the first semiconductor chip and the first electrode of the second semiconductor chip can be electrically conductively connected to a second contact layer of the component. For example, the second electrode of the second semiconductor chip is electrically conductively connected to a third contact layer of the component. The first contact layer, the second contact layer and the third contact layer can be arranged directly next to each other. However, it is possible for the first contact layer, the second contact layer and the third contact layer to be separated from each other by further intermediate contact layer/s. The component can have several such pairs of a first semiconductor chip and a second semiconductor chip.

According to at least one embodiment of the component, the semiconductor chips of the same pixel group or all semiconductor chips of the component are controllable both individually and in groups. In particular, any two or more semiconductor chips of the same pixel group are controllable individually, in pairs or in groups. The component can have a plurality of transistors that are configured to control the semiconductor chips. For example, the component has a driver circuit which has a plurality of transistors, the transistors being electrically connected to different semiconductor chips. The driver circuit is configured, for example, to control any number of semiconductor chips individually or in groups.

According to at least one embodiment of the component, the at least two semiconductor chips of the same pixel group are assigned to at least two adjacent rows or two adjacent columns of the semiconductor chips. If the pixel group has more than two semiconductor chips, it is possible that the semiconductor chips of the same pixel group are assigned to several rows and/or several columns of the semiconductor chips.

For example, a row of semiconductor chips refers to an arrangement in a horizontal form, such as along a longitudinal direction of the carrier or component. For example, the contact layers of the carrier or component are arranged in rows, such as two rows, along the longitudinal direction of the component. The semiconductor chips are located, for example, between the rows of contact layers in plan view. Accordingly, a column of semiconductor chips refers to an arrangement along a direction perpendicular to the longitudinal direction of the component.

According to at least one embodiment of the component, the pixel groups each form a contiguously formed multi-pixel. The contiguously formed multi-pixel can have at least two sub-pixels or a plurality of sub-pixels. Each multi-pixel can form an independent unit. For example, all semiconductor chips of the same multi-pixel are mechanically connected to each other, for example via a common encapsulation body. Each independent unit comprising at least two or more semiconductor chips can thus be arranged on the mounting surface or removed from the mounting surface in a single process step. In this sense, the interconnected multi-pixel can be described as an independent or monolithic unit.

According to at least one embodiment of the component, the semiconductor chips are arranged in a matrix-like manner in at least 4 rows and 10 to 25 columns on the mounting surface. The number of semiconductor chips of such a component can be at least 40, 60, 80 or 100. For example, the semiconductor chips form a plurality of pixel groups, each in the form of a contiguous multi-pixel. The contact layers may be arranged in at least two rows, with the rows of contact layers running parallel to the rows of semiconductor chips. The multi-pixel can be formed from at least two or more semiconductor chips, with the semiconductor chips of the same multi-pixel being assigned to at least two or more different rows or at least two or more different columns of the semiconductor chips.

The use of multi-pixel units enables requirements for headlight systems, such as adaptive front lighting systems, to be met. Advanced or more complex illumination scenarios can be realized from a pixel count of 40 to 60 pixels, for example. The number of pixels of the component can also be up to around 100. For example, the component has not just two rows of semiconductor chips but 4 or more than 4 rows of semiconductor chips.

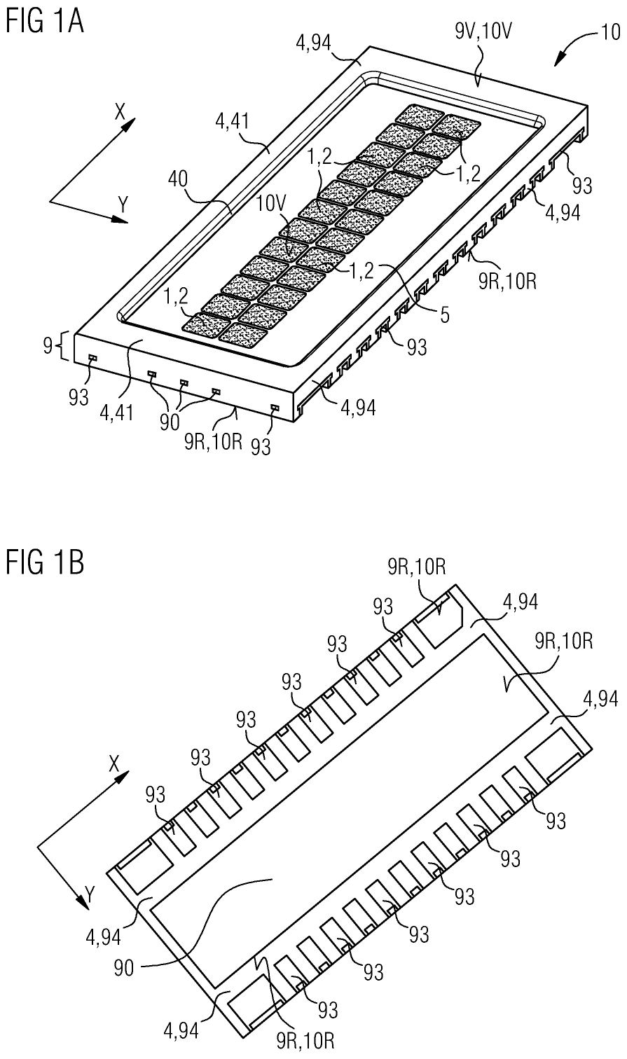

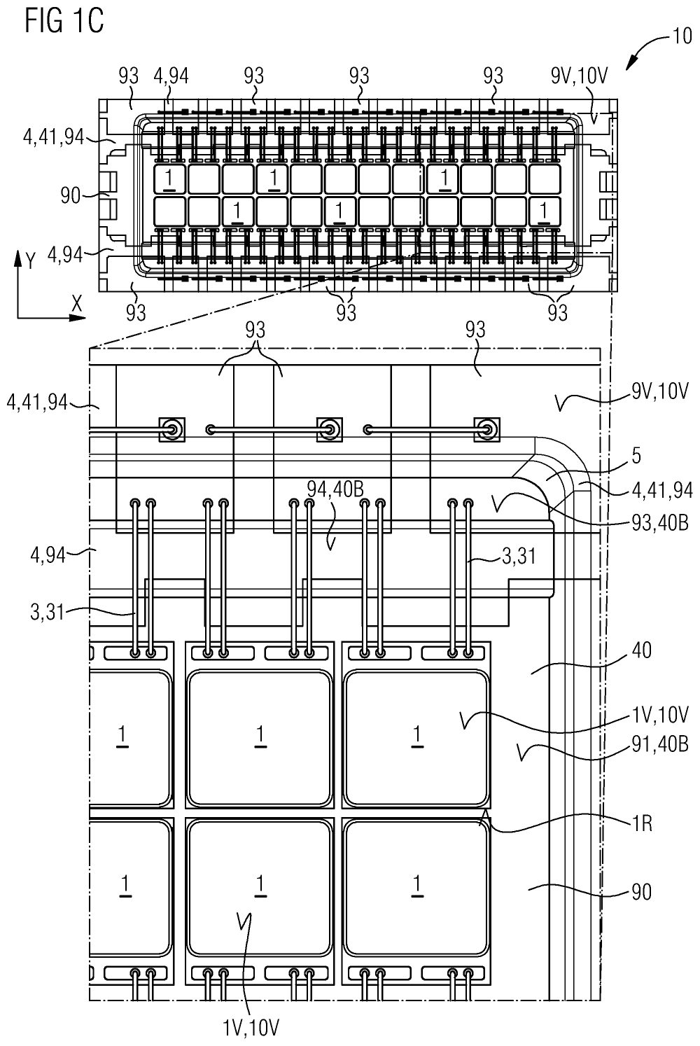

Further embodiments and further implementations of the component are apparent from the embodiments explained below in connection with FIGS. 1A to 3D.

FIGS. 1A, 1B and 1C show schematic representations of an embodiment of a component in perspective view as well as in plan view of a rear side and in plan view of a front side of the component,

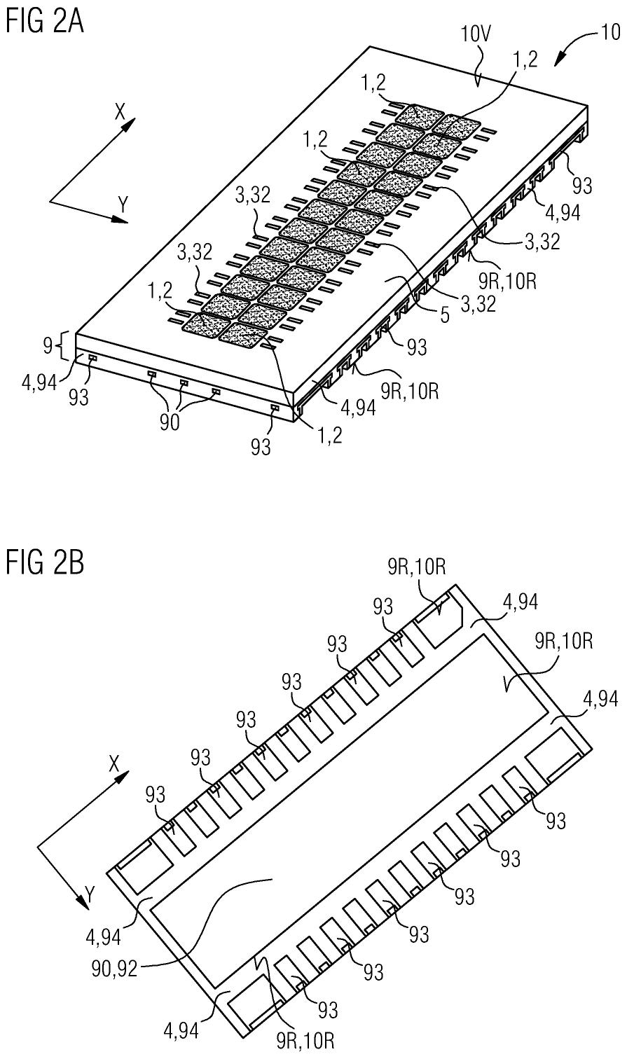

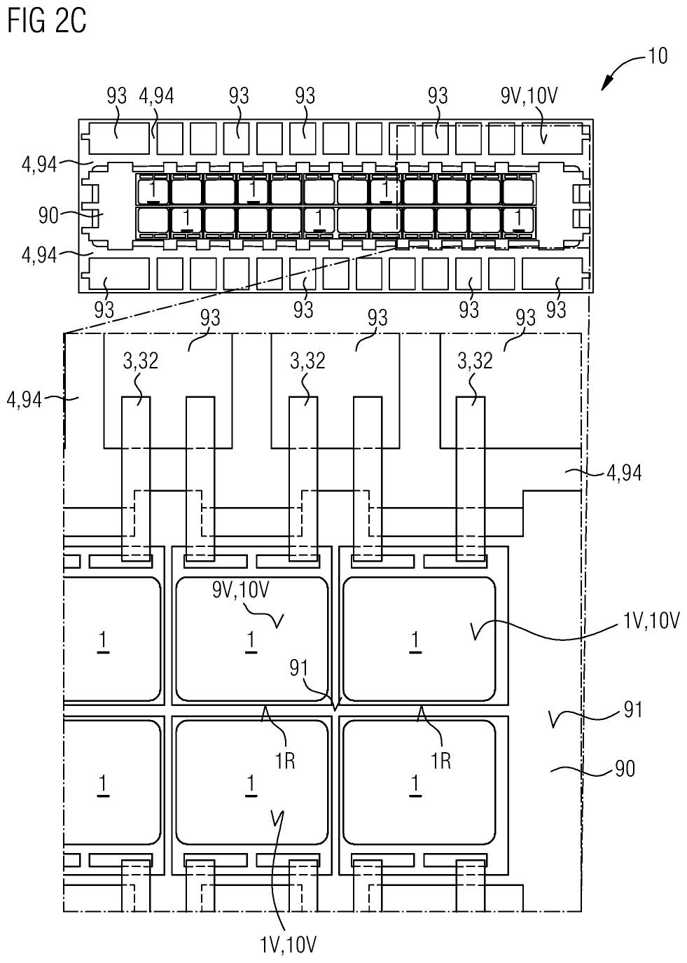

FIGS. 2A, 2B and 2C show schematic representations of a further embodiment of a component in perspective view and in plan view of a rear side and in plan view of a front side of the component, and

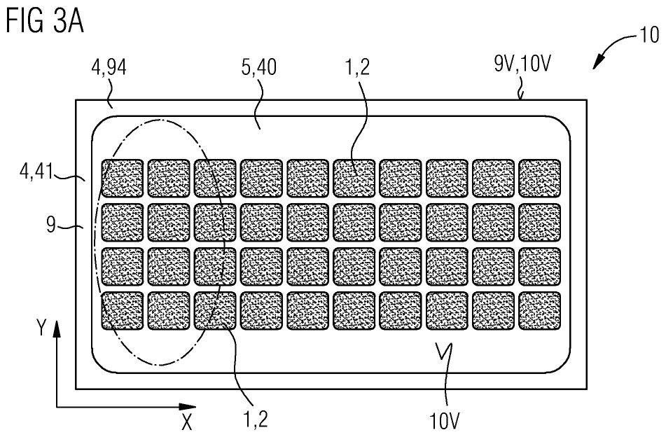

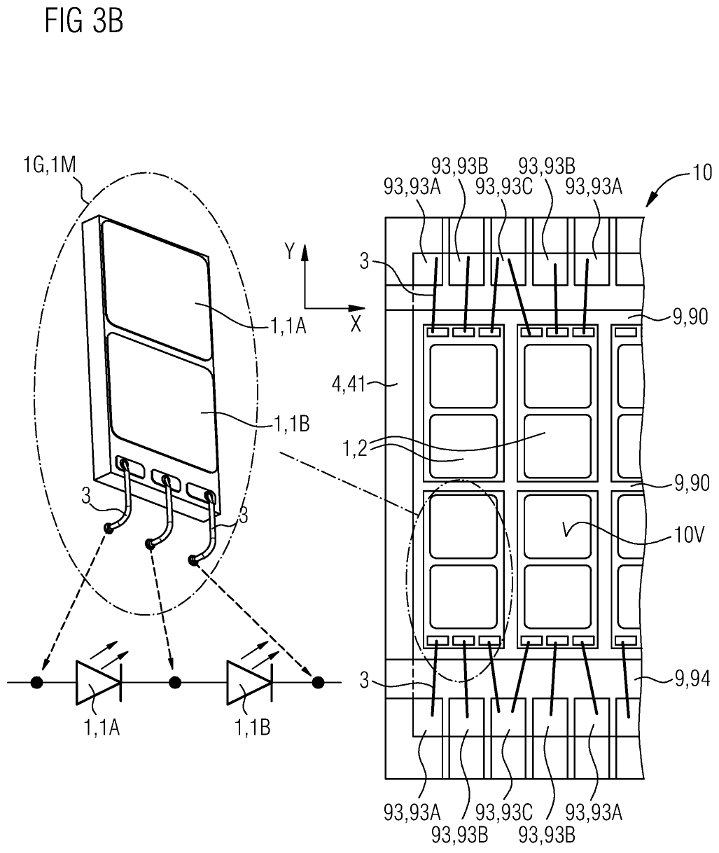

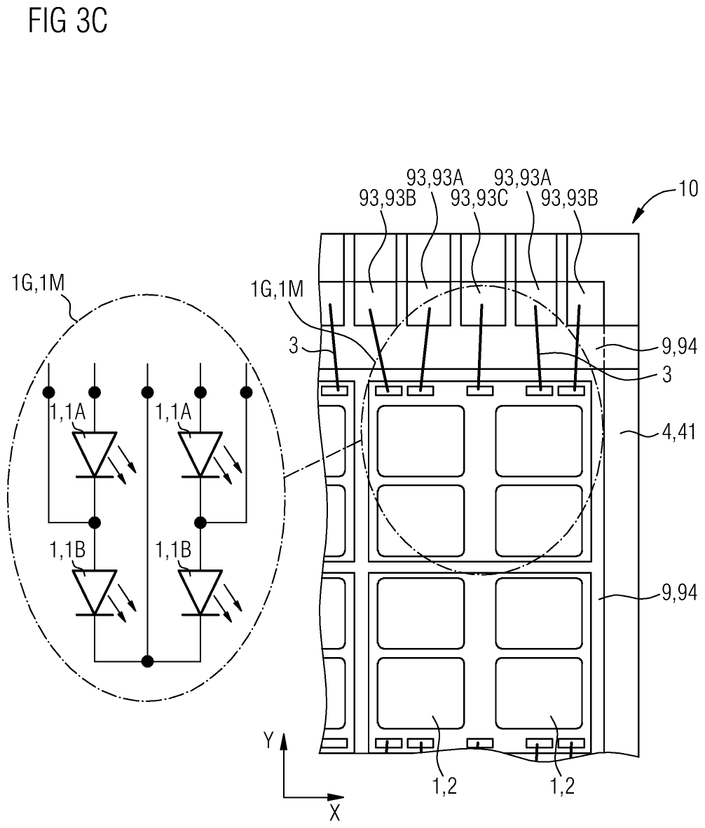

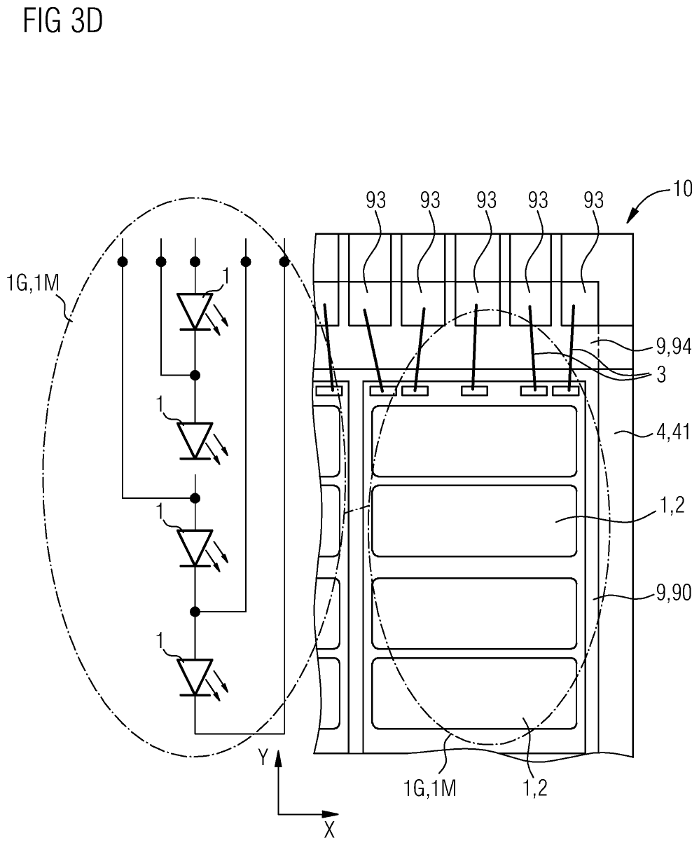

FIGS. 3A, 3B, 3C and 3D show schematic representations of further embodiments of a component in plan view of a front side of the component.

Identical, equivalent or equivalently acting elements are indicated with the same reference numerals in the figures. The figures are schematic illustrations and thus not necessarily true to scale. Comparatively small elements and particularly layer thicknesses can rather be illustrated exaggeratedly large for the purpose of better clarification.

FIG. 1A shows a component 10 in perspective view. The component 10 is in particular a light module, such as an ADB module. Such a light module can be used in a headlight, for example in a headlight of an automobile.

The component 10 has a carrier 9 and a plurality of semiconductor chips 1, wherein the semiconductor chips 1 are arranged on the carrier 9. The semiconductor chips 9 are, for example, LEDs, which are configured to generate electromagnetic radiation when the component 10 is in operation.

The carrier 9 has a housing body 4, a metallic carrier layer 90 and a plurality of contact layers 93. In particular, the metallic carrier layer 90 and the plurality of contact layers 93 form a lead frame which is surrounded, in particular encapsulated, by the housing material 94 of the housing body 4. However, the metallic carrier layer 90 is not configured for electrically contacting the semiconductor chips 1. The housing material 94 can be a molding material, which is formed to be in particular non-transmissive to radiation. For example, the housing material 94 is an epoxy material, such as a black epoxy material.

In plan view, the housing body 4 can be formed like a frame with an opening 40. The opening 40 is formed in particular by a depression in the housing body 4. In lateral directions, the opening 40 is enclosed by side walls 41 of the housing body 4. In lateral directions, the contact layers 93 and the metallic carrier layer 90 can be enclosed by the housing material 94. The contact layers 93 are spatially separated from each other and from the metallic carrier layer 90 in lateral directions. However, the contact layers 93 and the metallic carrier layer 90 are mechanically connected to each other by the housing material 94. In particular, the housing material 94 is electrically insulating. As a result, the contact layers 93 can be electrically insulated from each other and from the metallic carrier layer 90.

In FIGS. 1A and 1n the further figures, an X-direction denotes a lateral longitudinal direction of the component 10, whereas a Y-direction denotes a further lateral direction of the component 10, wherein the further lateral Y-direction is perpendicular to the longitudinal X-direction.

As shown schematically in FIG. 1A, the contact layers 93 and the metallic carrier layer 90 may have regions which are not covered by the housing material 94 on side surfaces of the housing body 4. Such regions of the contact layers 93 and/or the metallic carrier layer 90 may have traces of singulation. For example, the contact layers 93 and the metallic carrier layer 90 are formed from the same electrically conductive material.

Along the vertical direction, the contact layers 93 and/or the metallic carrier layer 90 can extend through the housing body 4. Both on a front side 9V and on a rear side 9R of the carrier 9, the contact layers 93 and/or the metallic carrier layer 90 can be freely accessible in places. The opening 40 of the housing body 4 has a bottom surface 40B, which is formed sectionally by surfaces of the contact layers 93, sectionally by surfaces of the metallic carrier layer 90 and sectionally by surfaces of the housing material 94.

The carrier 9 has a mounting surface 91 on which the semiconductor chips 1 are arranged. In particular, all radiation-emitting semiconductor chips 1 are arranged exclusively on the mounting surface 91, for example on the metallic carrier layer 90. It is possible that the component 10 has further optically inactive semiconductor chips that are formed as protective diodes. Such protective diodes can be partially or completely embedded in the housing body 4 of the carrier 9, i.e. in the housing material 94.

The radiation-emitting semiconductor chips 1 are only mechanically and not electrically connected to the metallic carrier layer 90. For example, the semiconductor chips 1 each have a rear side 1R that faces the metallic carrier layer 90. In particular, the rear side 1R of the semiconductor chip 1 is electrically insulating. For example, such a semiconductor chip 1 has an electrically insulating chip carrier, such as a ceramic carrier. Alternatively, it is possible for such a semiconductor chip 1 to have an electrically conductive chip carrier that is provided with an electrically insulating cover layer. The semiconductor chip 1 is electrically insulated from the metallic carrier layer 90 by the electrically insulating cover layer.

The semiconductor chips 1 each have a front side 1V facing away from the rear side 1R. The front side 1V is formed in particular as a radiation exit surface of the semiconductor chip 1. The front side 1V can be provided with a converter layer 2. The converter layer 2 is formed to convert short-wave electromagnetic radiation parts into long-wave electromagnetic radiation parts. For example, ultraviolet or blue radiation parts of the radiation emitted by the semiconductor chip 1 can be absorbed by the converter layer 2 and converted into green, yellow or red radiation parts. With the converter layer 2, the semiconductor chip 1 is configured in particular for generating white light.

The component 10 has a plurality of radiation-emitting semiconductor chips 1, which are arranged in exactly one row, in exactly two rows or in several rows and/or columns on the metallic carrier layer 90. Each of the semiconductor chips 1 can have its own converter layer 2. Alternatively, it is possible that the semiconductor chips 1 have a common converter layer 2, which in particular covers all of the semiconductor chips 1. The converter layer 2 can be a spray-coating layer or a converter wafer. For example, the component 10 has at least two rows of semiconductor chips 1, each row having, for example, at least 5, 8, 10, 12 or at least 15 semiconductor chips.

The semiconductor chips 1 arranged on the metallic carrier layer 90 can be electrically contacted via the contact layers 93. For example, the semiconductor chips 1 are electrically conductively connected to the contact layers 93 via electrical connections 3 (see FIG. 1C or 2C). Since the contact layers 93 are spatially spaced from each other and from the metallic carrier layer 90 in lateral directions, there are intermediate regions between the contact layers 93 and between the metallic carrier layer 90 and the contact layers 93. In plan view, the electrical connections 3 can bridge the intermediate regions between the metallic carrier layer 90 and the contact layers 93. The intermediate areas can be filled with the housing material 94.

According to FIG. 1A, the component 10 has an encapsulation layer 5, which is formed to be for instance radiation reflective. The encapsulation layer 5 can directly or indirectly adjoin the semiconductor chips 1, the converter layer/s 2 and/or the housing body 4 in lateral directions. The encapsulation layer 5 can have a matrix material with reflective particles or white particles embedded therein. In plan view, the front sides 1V of the semiconductor chips 1 may not be covered by the encapsulation layer 5, at least in places. In particular, the radiation exit surfaces of the semiconductor chips 1 are not covered by the encapsulation layer 5. In plan view, the converter layer/s 2 is/are free of being covered by the encapsulation layer 5. The encapsulation layer 5 is configured to increase the contrast and the luminance of the component 10.

The component 10 has a front side 10V (see also FIGS. 1C and 2C). The front side 10V of the component 10 can be formed sectionally by surfaces of the housing body 4, the encapsulation layer 5 and/or the converter layer/s 2. The component 10 has a rear side 10R facing away from the front side 10V, wherein the rear side 10R of the component 10 is shown schematically in FIG. 1B.

The rear side 10R of the component 10 can be formed by the rear side 9R of the carrier 9. The rear side 9R or 10R is formed sectionally by the surface of the metallic carrier layer 90, sectionally by the surface of the housing body 4 and sectionally by the surfaces of the contact layers 93. The component 10 can be electrically contacted externally via the rear side 10R, in particular exclusively via the rear side 10R. In this sense, the component 10 is a surface mounted component 10. To avoid a possible electrical short circuit, the metallic carrier layer 90 can be provided with an electrically insulating layer on the rear side 9V of the carrier 9.

As shown schematically in FIG. 1B, the metallic carrier layer 90 has a rear side surface or a front side surface that is larger than each of the rear side or front side surfaces of the contact layers 93, for example at least twice, three times, four times or five times larger than the sum of all rear side surfaces or all front side surfaces of all contact layers 93. While the metallic carrier layer 90 represents a large thermal pad, the surfaces of the contact layers 93 in particular form individually addressable electrical connection surfaces. The metallic carrier layer 90 is thus formed as the main carrier layer of the lead frame of the carrier 9. Since the radiation-emitting semiconductor chips 1 are arranged exclusively on the metallic carrier layer 90, they do not have any overlaps with the contact layers 93 and/or with the housing body 4 when viewed from above on the component 10.

FIG. 1C shows the front side 10V of the component 10, wherein a section of the front side 10V is shown enlarged. The component 10 according to FIG. 1C has two strands or rows of semiconductor chips 1, which are arranged exclusively on the metallic carrier layer 90. The semiconductor chips 1 each have electrical contact points on their front side 1V, which are electrically conductively connected to the contact layers 93 via electrical connections 3. In plan view, the electrical contact points of the respective semiconductor chip 1 are arranged next to the converter layer 2 or next to the radiation exit surface of the respective semiconductor chip 1. The electrical connections 3 are in the form of wire connections in particular in the form of bonding wire connections.

As shown schematically in FIG. 1C, the contact layers 93 can be covered sectionally by the housing material 94 of the housing body 4 in plan view.

According to FIG. 1C, the carrier 9 has two edge-side rows of contact layers 93, with the metallic carrier layer 90 being arranged in a lateral direction between the two rows of contact layers 93. Each of the semiconductor chips 1 is electrically conductively connected to two contact layers 93. It is possible that two neighboring semiconductor chips 1 are electrically conductively connected to a common contact layer 93. The semiconductor chips 1 of the same series can be electrically connected in series with one another.

As shown schematically in the enlarged section of the front side 1V of the component 10, the electrical connections 3 or 31 may be partially or completely covered by the encapsulation layer 5. The encapsulation layer 5 thus protects the electrical connections 3 from external mechanical influences and from environmental influences. For example, the encapsulation layer 5 is located exclusively within the opening 40 of the housing body 4.

As shown schematically in FIG. 1C, the metallic carrier layer 90 can have edge regions that are formed in a step-like manner. Compared to the other regions of the metallic carrier layer 90, the step-like edge regions have reduced vertical layer thicknesses. The step-like edge regions serve in particular as anchoring structures to which the housing material 94 is anchored.

The component 10 shown in FIG. 2A essentially corresponds to the component 10 shown in FIG. 1A. In contrast to this, the electrical connections 3 are formed in particular as planar electrical connections 32. In further contrast to FIG. 1A, the encapsulation layer 5 can completely cover the housing body 4. The encapsulation layer 5 can also completely cover the electrical connections 3 in plan view. Referring to FIG. 2A, it is possible for the housing body 4 to be flush with the contact layers 93 and/or with the carrier layer 90 on the front side 9V of the carrier 9. In other words, it is possible that the housing body 4 on the front side 9V of the carrier 9 does not protrude vertically beyond the contact layers 93 and/or or beyond the carrier layer 90. Moreover, the features disclosed in connection with the component 10 shown in FIG. 1A can be used for the component 10 shown in FIG. 2A.

FIG. 2B shows a rear side 10R of the component 10 shown in FIG. 2A. The rear side 10R shown in FIG. 2B corresponds to the rear side 10R of a component 10 shown in FIG. 1B.

FIG. 2C shows a front side 10V of the component 10 shown in FIG. 2A with an enlarged section. Analogous to FIG. 2A, the component 10 shown in FIG. 2C corresponds to the component 10 shown in FIG. 1C except for the configuration of the electrical connection 3, the encapsulation layer 5 and, if applicable, the housing body 4 on the front side 9V of the carrier 9.

In comparison to FIG. 1C, FIG. 2C explicitly shows that the converter layers 2 are formed as individual layers. In particular, the converter layers 2 are converter plates that are assigned one-to-one to the semiconductor chips 1.

FIG. 2C also shows schematically that the housing body 4 can be formed as a flat molded body (flat mold). In particular, the housing material 94 is located only on the side of the metallic carrier layer 90 and on the side of the contact layers 93. On the front side 9V and/or on the rear side 9R of the carrier 9, the housing body 4 in particular does not project vertically beyond the metallic carrier layer 90 and/or beyond the contact layers 93. The carrier layer 90 may have lowered areas on which the planar electrical connections 32 are formed. The depressed areas may be partial or semi-etched areas of the carrier layer 90. The depressed or stepped regions of the carrier layer 90 may be covered with the housing material 94 or other electrically insulating material that electrically insulates the planar electrical connections 32 from the carrier layer 90.

In contrast to FIG. 1C, according to FIG. 2C, it is possible for the mounting surface 91 to be provided with an electrically insulating additional layer 92. The electrically insulating additional layer 92 can electrically insulate the semiconductor chips 1 from the common metallic carrier layer 90. The electrically insulating additional layer 92 may partially or completely cover the mounting surface 91. For example, the electrically insulating additional layer 92 covers at least the areas of the mounting surface 91 on which the semiconductor chips 1 are arranged.

The component 10 shown in FIG. 3A essentially corresponds to the component 10 shown in FIG. 1A. In contrast, the component 10 shown in FIG. 3A has four rows of semiconductor chips 1. Each row of semiconductor chips 1 has at least 5, 8, 10 or 12 semiconductor chips 1. As an example, ten semiconductor chips 1 per row are shown in FIG. 3A. Accordingly, the component 10 shown in FIG. 3A has ten columns of semiconductor chips 1. Here, a row refers to an arrangement of the semiconductor chips 1 along the X direction, i.e. along the lateral longitudinal direction X of the component 10, whereas a column refers to an arrangement of the semiconductor chips 1 along the lateral Y direction perpendicular to the X direction.

FIG. 3B shows a section of the component 10 labeled in FIG. 3A. The semiconductor chips 1 of the component 10 may be divided in pairs into a plurality of pixel groups 1G. Each of the pixel groups 1G can have two interconnected semiconductor chips 1. Such a pixel group 1G forms a contiguously formed multi-pixel 1M, wherein the semiconductor chips 1 of the multi-pixel 1M each form a subpixel of the multi-pixel 1M. Each subpixel can have a light-emitting surface of less than 1 mm², for example 750 μm×560 μm. Each of the semiconductor chips 1 of the multi-pixel 1M can have a width and/or length of less than 1 mm.

FIG. 3B shows a pixel group 1G that has a contiguous multi-pixel 1M consisting of two electrically interconnected semiconductor chips 1. A multi-pixel 1M implemented in such a contiguous manner can be referred to as a 1×2 multi-pixel. Each contiguously formed multi-pixel 1M can have at least a first semiconductor chip 1A and a second semiconductor chip 1B. The first semiconductor chip 1A and the second semiconductor chip 1B are electrically connected in series with each other. The multi-pixel 1M is arranged in such a way that the first semiconductor chip 1A is assigned to a first row of the semiconductor chips 1, and the second semiconductor chip 1B is assigned to a second row of the semiconductor chips 1, which is different from the first row.

The first semiconductor chip 1A and the second semiconductor chip 1B are controllable individually or in pairs, for example, via a driver circuit which has transistors, for example. A schematic interconnection of the semiconductor chips 1A and 1B is shown in FIG. 3B.

The first semiconductor chip 1A and the second semiconductor chip 1B may each have a first electrode and a second electrode. For example, the first electrode is an anode and the second electrode is a cathode, or vice versa. The first electrode of the first semiconductor chip 1A may be electrically conductively connected to a first contact layer 93A via an electrical connection 3, which is a bonding wire connection or a planar electrical connection. The second electrode of the first semiconductor chip 1A and the first electrode of the second semiconductor chip 1B may be electrically conductively connected to a second contact layer 93B. The second electrode of the second semiconductor chip 1B may be electrically conductively connected to a third contact layer 93C. Depending on whether the first contact layer 93A, the second contact layer 93B and/or the third contact layer 93C are electrically contacted externally, the first semiconductor chip 1A and the second semiconductor chip 1B can be driven individually or in pairs.

According to FIG. 3B, it is possible that the four rows of semiconductor chips 1 are formed by two rows of the pixel groups 1G and the multi-pixels 1M, respectively, wherein the pixel groups 1G and the multi-pixels 1M, respectively, are electrically contacted via the laterally arranged rows of contact layers 93. For example, all semiconductor chips 1 of the pixel groups 1G are arranged along the lateral Y-direction between the two rows of contact layers 93. All semiconductor chips 1 of the pixel groups 1G can be electrically conductively connected to the contact layers 93 via the electrical connections 3.

It is possible that neighboring multi-pixels 1M or the multi-pixels 1M of the component 10 are electrically conductively connected to each other via electrical connections 3, for example electrically conductively connected to each other in series. For example, the component 10 has two electrical connections 3, each of which is electrically conductively connected at one end to one of the multi-pixels 1M and electrically conductively connected at another end to the same contact layer 93. It is also possible that the two electrical connections 3 are each electrically conductively connected at the other ends to two contact layers 93, with the two contact layers 93 being electrically conductively connected to each other via a further electrical connection.

The component 10 shown in FIG. 3C essentially corresponds to the component 10 shown in FIG. 3B. In contrast, each of the pixel groups 1G or each multi-pixel 1M has four semiconductor chips 1. The semiconductor chips 1 of the same multi-pixel 1M are assigned to two adjacent rows and two adjacent columns of the semiconductor chips 1. A multi-pixel 1M formed in this contiguous manner can be referred to as a 2×2 multi-pixel. All semiconductor chips 1A and 1B of the same multi-pixel 1M can be connected in series. As shown schematically in FIG. 3C, the semiconductor chips 1A and 1B of the same multi-pixel 1M can nevertheless be controlled individually or in groups via the contact layers 93, for example via five contact layers 93.

The component 10 shown in FIG. 3D essentially corresponds to the component 10 shown in FIG. 3C.

In contrast, the multi-pixel 1M has four neighboring semiconductor chips 1. A multi-pixel 1M formed in such a contiguous manner can be referred to as a 1×4 multi-pixel. In contrast to FIG. 3C, the semiconductor chips 1 of the same multi-pixel 1M according to FIG. 3D are assigned to four adjacent rows of semiconductor chips 1. As in FIG. 3C, all semiconductor chips of the same multi-pixel 1M are controllable individually or in groups via the contact layers 93, for example via five contact layers 93.

As shown schematically in FIGS. 3C and 3D, it is possible that any number of the semiconductor chips 1 of the same multi-pixel 1M can be driven. The arrangements and interconnections of semiconductor chips 1 illustrated in FIGS. 3A to 3D are merely examples of the present disclosure, so that the present disclosure is not necessarily limited to such examples. For example, the component 10 may have more than four rows of semiconductor chips 1. It is also possible that the component 10 comprises a plurality of multi-pixels 1M, each comprising more than four semiconductor chips 1.

According to FIGS. 3A to 3D, the component 10 can be formed using multi-pixels 1G or 1M instead of individual pixels as in FIGS. 1A to 2C. In particular, 1×2-, 1×4-, 2×2-multi-pixels are described in this context, so that 4-row modules can be realized wherein simple and convenient electrically contacting the semiconductor chips 1 can be made from two sides. In general, m×n multi-pixels can also be realized, where m and n can be natural numbers greater than or equal to 1, 2, 3 or 4.

For electrically contacting the 2×12 individual pixels or individual semiconductor chips 1 shown in FIGS. 1A to 2C, 2×13 electrical contacts or contact layers 93 are sufficient, for example. For 2×n individual pixels or individual semiconductor chips 1, for example, 2×(n+1) electrical contacts or contact layers 93 would be sufficient. For electrically contacting the m×n multi-pixel shown in FIGS. 3A to 3D, m×(n+1) electrical contacts or contact layers 93 may be sufficient, depending on the type of internal electrical interconnection. In this case, the semiconductor chips 1 of the same multi-pixel 1M are controllable individually, in pairs and/or in groups.

By combining a larger number of semiconductor chips 1 and QFN lead frames, a cost-effective, thermally optimized component configuration can be realized. Not only individual semiconductor chips 1 but also multi-pixels 1M each consisting of at least two semiconductor chips 1 can be placed on the mounting surface 91 and electrically contacted with the lateral contact layers 93. In comparison with FIGS. 1A to 2C, the Y axis, i.e. the short axis, can be extended in a simple manner as shown in FIGS. 3A to 3D. For example, a QFN approach can be extended to application-relevant four-row or multi-row components 10. This allows illuminance levels with (LEAs)/pixel in the range of 0.5 m² to be achieved, where LEA is an abbreviation for light-emitting area.

In particular, the following technical features can be achieved for more complex lighting scenarios, for example 4×10 to approximately 4×25 pixel arrays with 0.5 mm² LEA per pixel (e.g. 20-50 mm² LEA in total), wherein the semiconductor chips 1 or the multi-pixels 1M are controllable individually or in groups. Compared to individual pixels each consisting of a single semiconductor chip 1, i.e. compared to monolithic approaches, a proposed structure of a component 10 consisting of individual multi-pixels 1M can lead to so-called yield losses in the manufacturing process of the semiconductor chips 1 not scaling with the total LEA of the component 10. Sequential electrical chip connections, for example via the electrical connections 3, lead to higher overall yield and to cost savings, for example in the manufacture of AFS or ADB modules, for example in the low resolution range.

The use of the multi-pixel 1M can also mean that more complex, fanned-out, so-called fan-out circuits can be avoided. For example, as shown schematically in FIGS. 3B to 3D, the electrodes of the individual semiconductor chips 1, such as the anodes and cathodes of the individual semiconductor chips 1 or the p- and n-contacts of the individual semiconductor chips 1, can be routed separately to individual electrical contact layers 93 via electrical connections 3.

Finally, the electrical connections 3 can be protected, for example in the form of bonding wire connections 31 or planar electrical connections, by means of a highly reflective encapsulation material. In this case, the light emitted to the side by the converter material of the converter layer 2 can be reflected back into the converter layer 2. This can lead to a high contrast on the front side 10V of the component 10. The converter layer 2 can be realized by a thin spray coating layer or by a thin converter plate.

This patent application claims the priority of the German patent application DE 10 2021 125 056.0, the disclosure content of which is hereby included by reference.

The invention is not restricted to the embodiments by the description of the invention made with reference to embodiments. The invention rather comprises any novel feature and any combination of features, including in particular any combination of features in the claims, even if this feature or this combination is not itself explicitly indicated in the claims or embodiments.

### LIST OF REFERENCE SYMBOLS

10 Component
10V Front side of the component
10R Rear side of the component
1 Semiconductor chip
1A First semiconductor chip
1B Second semiconductor chip
1V Front side, Radiation exit surface of the semiconductor chip
1R Rear side of the semiconductor chip
1G Pixel group
1M Contiguous multi-pixel
2 Converter layer
3 Electrical connection
31 Bond wire connection
32 Planar electrical connection
4 Housing body
40 Opening of the housing body
41 Side wall of the housing body
40B Bottom surface of the housing body
5 Encapsulation layer
9 Carrier
9V Front side of the carrier
9R Rear side of the carrier
90 Metallic carrier layer
91 Mounting surface
92 Electrically insulating additional layer
93 Contact layer
93A First contact layer
93B Second contact layer
93C Third contact layer
94 Housing material
X lateral longitudinal direction/longitudinal axis
Y lateral direction perpendicular to the longitudinal direction/transverse axis

1. A component having a plurality of semiconductor chips and a carrier, wherein
the carrier has a common metallic carrier layer with a mounting surface on which the semiconductor chips are arranged,
the semiconductor chips are thermally but not electrically conductively connected to the common metallic carrier layer,
the carrier has a plurality of contact layers which are arranged next to one another and next to the common carrier layer in lateral directions and are configured for electrically contacting the component and thus for electrically contacting the semiconductor chips,
the carrier has an electrically insulating housing material which holds the common metallic carrier layer and the contact layers together, wherein the common metallic carrier layer and the contact layers are adjacent to the housing material and are electrically insulated from each other by the electrically insulating housing material, and
the semiconductor chips are configured to generate electromagnetic radiation during operation of the component and are arranged in at least two rows on the mounting surface, wherein each row comprises at least five semiconductor chips and lateral distances between the semiconductor chips or between the rows of semiconductor chips are less than 150 μm.

2. The component according to claim 1,
wherein the semiconductor chips have chip carriers or rear sides, the chip carriers or the rear sides facing the common carrier layer and being electrically insulating.

3. The component according to claim 1, wherein the mounting surface is provided with an electrically insulating additional layer which electrically insulates the semiconductor chips from the common metallic carrier layer.

4. The component according to claim 1, wherein the semiconductor chips are electrically conductively connected to the contact layers via bonding wire connections.

5. The component according to claim 1, wherein the semiconductor chips are electrically conductively connected to the contact layers via planar electrical connections.

6. The component according to claim 1, wherein the carrier has a front side and a rear side facing away from the front side, the front side comprising the mounting surface and the contact layers being accessible both on the front side and on the rear side of the carrier.

7. The component according to claim 1, wherein the semiconductor chips are controllable in groups or individually via the plurality of contact layers.

8. The component according to claim 1, comprising a housing body which is formed from the housing material, the component being formed as a QFN component (Quad Flat No-leads), wherein the contact layers are at most flush with the housing body in lateral directions and do not project laterally beyond the housing body.

9. The component according to claim 1, comprising a housing body which is formed from the housing material and is of frame-like design in plan view, wherein
the housing body has an opening which, in plan view, is framed by side walls of the housing body,
the contact layers are partially covered by the side walls of the housing body and partially exposed in the opening, and
the opening has a bottom surface which is formed sectionally by the mounting surface, sectionally by surfaces of the contact layers and sectionally by surfaces of the housing material.

10. The component according to claim 1, comprising an encapsulation layer which is formed from a matrix material having reflective particles embedded therein, wherein in plan view, the encapsulation layer partially covers the mounting surface and the contact layers, and wherein radiation exit surfaces of the semiconductor chips are uncovered by the encapsulation layer.

11. The component according to claim 10, comprising a converter layer or a plurality of the converter layers, wherein
the converter layer or the plurality of converter layers is configured for converting at least some radiation parts of the electromagnetic radiations emitted by the semiconductor chips during operation of the component, and
the converter layer or the plurality of converter layers is/are laterally adjacent to the encapsulation layer.

12. The component according to claim 1, wherein the semiconductor chips are arranged in at least four rows on the mounting surface, each of the at least four rows having at least five semiconductor chips.

13. The component according to claim 1, comprising a plurality of pixel groups, each of which has at least two semiconductor chips, the at least two semiconductor chips of the same pixel group each forming a subpixel and being electrically interconnected internally.

14. The component according to claim 13,
wherein the at least two semiconductor chips of the same pixel group comprise a first semiconductor chip and a second semiconductor chip, wherein
the first semiconductor chip and the second semiconductor chip each have a first electrode and a second electrode,
the first electrode and the second electrode are assigned to different electrical polarities of the component,
the first electrode of the first semiconductor chip is electrically conductively connected to a first contact layer,
the second electrode of the first semiconductor chip and the first electrode of the second semiconductor chip are electrically conductively connected to a second contact layer, and
the second electrode of the second semiconductor chip is electrically conductively connected to a third contact layer.

15. The component according to claim 13, wherein the semiconductor chips of the same pixel group are controllable both individually and in groups.

16. The component according to claim 13, wherein the at least two semiconductor chips of the same pixel group are assigned to at least two adjacent rows or two adjacent columns of the semiconductor chips.

17. The component according to claim 13, wherein the pixel groups each form a contiguous multi-pixel which has at least two subpixels or a plurality of subpixels.

18. The component according to claim 13, wherein the semiconductor chips are arranged in a matrix-like manner in at least 4 rows and 10 to 25 columns on the mounting surface, the semiconductor chips forming a plurality of pixel groups each in the form of a contiguously formed multi-pixel, wherein
the contact layers are arranged at least in two rows, the rows of the contact layers running parallel to the rows of the semiconductor chips, and
the multi-pixel is formed from at least two semiconductor chips, the semiconductor chips of the same multi-pixel being assigned to at least two different rows or at least two different columns of the semiconductor chips.

19. A headlight comprising the component according to claim 1.

20. The component according to claim 1,
wherein the carrier has two edge-side rows of contact layers, the metallic carrier layer being arranged in a lateral direction between the two rows of contact layers.
